(19) United States
(12) Patent Application Publication
(10) Pub. No.: US 2024/0120447 A1
(43) Pub. Date: Apr. 11, 2024

(54) DISPLAY DEVICE AND METHOD OF MANUFACTURING THE SAME

(71) Applicant: Samsung Display Co., LTD., Yongin-si (KR)

(72) Inventors: KYUNGHEE LEE, Yongin-si (KR); OHJEONG KWON, Yongin-si (KR); WOOYOUNG KIM, Yongin-si (KR); JUNG-WOO LEE, Yongin-si (KR)

(73) Assignee: Samsung Display Co., LTD., Yongin-si (KR)

(21) Appl. No.: 18/322,799

(22) Filed: May 24, 2023

(30) Foreign Application Priority Data
Oct. 6, 2022 (KR) 10-2022-0128174

(51) Int. Cl. H01L 33/44; H01L 33/52

(52) U.S. Cl. CPC H01L 33/44; H01L 33/52; H01L 2933/0025; H01L 2933/005

(57) ABSTRACT

A display device includes a substrate including a light emitting area and a non-light emitting area, a light emitting element disposed in the light emitting area on the substrate, an encapsulation layer disposed on the light emitting element, and a reflection adjustment layer disposed on the encapsulation layer. The reflection adjustment layer includes a first portion adjacent to the encapsulation layer and a second portion disposed on the first portion, and a curing rate of the first portion a curing rate of the second portion are different.

### CROSS-REFERENCE TO RELATED APPLICATION(S)

This application claims priority to and benefits of Korean Patent Application No. 10-2022-0128174 under 35 U.S.C. § 119, filed on Oct. 6, 2022, in the Korean Intellectual Property Office (KIPO), the entire contents of which are incorporated herein by reference.

### BACKGROUND

### 1. Technical Field

Embodiments relate to a display device providing visual information and a method of the display device.

### 2. Description of the Related Art

With the development of information technology, the importance of display device, which is a connection medium between a user and information, has been highlighted. Accordingly, the use of display devices such as a liquid crystal display device (“LCD”), an organic light emitting display device (“OLED”), a plasma display device (“PDP”), quantum dot display device, and the like is increasing.

The display device may display an image on the screen and provide the image to the user. As external light incident on the display device is reflected from the surface of the display device, the display quality of the display device may decrease. In order to prevent this, a polarizing film, a color filter, a reflection adjustment layer, and the like are used. In addition, research is being conducted to suppress reflection of external light.

### SUMMARY

Embodiments provide a display device with improved display quality.

Embodiments provide a method of manufacturing the display device.

A display device according to an embodiment may include a substrate including a light emitting area and a non-light emitting area, a light emitting element disposed in the light emitting area on the substrate, an encapsulation layer disposed on the light emitting element, and a reflection adjustment layer disposed on the encapsulation layer. The reflection adjustment layer may include a first portion adjacent to the encapsulation layer and a second portion disposed on the first portion, and a curing rate of the first portion a curing rate of the second portion may be different.

In an embodiment, the curing rate of the second portion may be greater than the curing rate of the first portion.

In an embodiment, the reflection adjustment layer may include an acrylate monomer and an acrylate network.

In an embodiment, an acrylate conversion rate of the second portion may be greater than or equal to about 0.1 times of an acrylate conversion rate of the first portion.

In an embodiment, the acrylate conversion rate of the second portion may be in a range of about 0.1 times to about 0.3 times of the acrylate conversion rate of the first portion.

In an embodiment, a ratio of the acrylate network to the acrylate monomer included in the second portion may be greater than a ratio of the acrylate network to the acrylate monomer included in the first portion.

In an embodiment, a thickness of the second portion may be in a range of about 0.1 times to about 0.9 times of a sum of a thickness of the first portion and the thickness of the second portion in a thickness direction of the substrate.

In an embodiment, the display device may further include a light blocking pattern disposed on the encapsulation layer.

In an embodiment, the reflection adjustment layer may cover the light blocking pattern.

In an embodiment, the display device may further include a capping layer disposed on the light emitting element, and an antireflection layer disposed between the capping layer and the encapsulation layer and including an inorganic material.

In an embodiment, the antireflection layer may include at least one of bismuth (Bi), ytterbium (Yb), tungsten (W), and tungsten trioxide (WO₃).

In an embodiment, the reflection adjustment layer may include a dye or a pigment.

In an embodiment, the first portion and the second portion may be cured by a plasma dry etching process.

In an embodiment, the display device may further include a protective film disposed on the second portion.

According to an embodiment, a method of manufacturing a display device may include forming a light emitting element on a substrate including a light emitting area and a non-light emitting area, forming an encapsulation layer on the light emitting element, forming a reflection adjustment layer on the encapsulation layer, and forming a first portion adjacent to the encapsulation layer and a second portion disposed on the first portion by curing a surface of the reflection adjustment layer. A curing rate of the first portion and a curing rate of the second portion may be different.

In an embodiment, the curing rate of the second portion may be greater than the curing rate of the first portion.

In an embodiment, the curing of the surface of the reflection adjustment layer may be performed by a plasma dry etching process.

In an embodiment, the curing of the surface of the reflection adjustment layer may include converting an acrylate monomer into an acrylate network by curing the acrylate monomer included in the reflection adjustment layer.

In an embodiment, the method of manufacturing the display device may further include forming a capping layer on the light emitting element, and forming an antireflection layer including an inorganic material between the capping layer and the encapsulation layer.

In an embodiment, the method of manufacturing the display device may further include forming a protective film on the reflection adjustment layer.

The display device according to an embodiment may include a substrate including a light emitting are and a non-light emitting area, a light emitting element disposed in the light emitting area on the substrate, an encapsulation layer disposed on the light emitting element, and a reflection adjustment layer disposed on the encapsulation layer. The reflection adjustment layer may include a first portion adjacent to the encapsulation layer and a second portion disposed on the first portion, and a curing rate of the first portion and a curing rate of the second portion may be different.

Accordingly, a dye or pigment of the reflection adjustment layer RCL may be prevented from moving into the protective film PF. In addition, the surface elasticity coefficient of the display device may increase.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to an embodiment.

FIG. 2 is a schematic cross-sectional view taken along line I-I′ of FIG. 1.

FIG. 3 is a schematic cross-sectional view illustrating region X of FIG. 2.

FIGS. 4A and 4B are experimental data showing transmittance of a protective film according to a comparative embodiment and an embodiment.

FIGS. 5 to 11 are schematic cross-sectional views illustrating a method of manufacturing the display device of FIG. 2 according to an embodiment.

FIG. 12 is a schematic diagram illustrating the display device of FIG. 1 implemented as a television according to an embodiment.

FIG. 13 is a schematic diagram illustrating the display device of FIG. 1 implemented as a smart phone according to an embodiment.

### DETAILED DESCRIPTION OF THE EMBODIMENTS

Hereinafter, display devices in accordance with embodiments will be described in more detail with reference to the accompanying drawings. The same reference numerals are used for the same components in the drawings, and redundant descriptions of the same components will be omitted.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

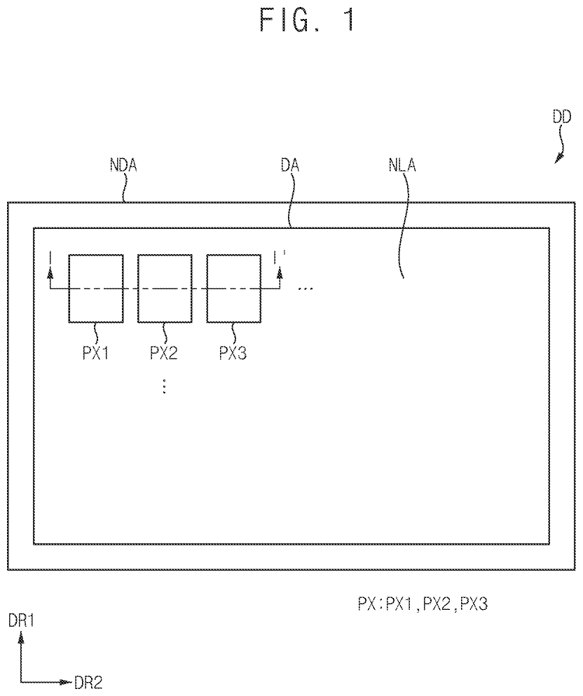

FIG. 1 is a plan view illustrating a display device according to an embodiment.

Referring to FIG. 1, a display device DD according to an embodiment may include a display area DA and a non-display area NDA. Multiple pixels PX may be disposed in the display area DA. The pixels PX may include a first pixel PX1, a second pixel PX2, and a third pixel PX3. Each of the first pixel PX1, the second pixel PX2, and the third pixel PX3 may be an area in which light emitted from a light emitting element is emitted to the outside of the display device DD. For example, the first pixel PX1 may emit first light, the second pixel PX2 may emit second light, and the third pixel PX3 may emit third light. In an embodiment, the first light may be red light, the second light may be green light, and the third light may be blue light. However, the disclosure is not limited thereto. For example, the pixels PX may be combined to emit yellow, cyan, and magenta light.

The pixels PX may emit four or more colors of light. For example, the pixels PX may be combined to emit at least one of yellow, turquoise, and deep red light in addition to red, green, and blue light. The pixels PX may be combined to further emit white light.

The pixels PX may be repeatedly arranged in a first direction DR1 and a second direction DR2 intersecting the first direction DR1 in a plan view. For example, the second pixel PX2 may be disposed adjacent to the first pixel PX1. For example, the second pixel PX2 may be disposed adjacent to the first pixel PX1 in the second direction DR2.

The non-display area NDA may be located adjacent to the display area DA. In an embodiment, the non-display area NDA may surround at least a portion of the display area DA. A driving unit (not illustrated) may be disposed in the non-display area NDA. The driving unit may provide signals or voltages to the pixels PX. For example, the driving unit may include a data driving unit, a gate driving unit, and the like. The non-display area NDA may not display an image.

In the specification, a plane may be defined by the first direction DR1 and the second direction DR2 intersecting the first direction DR1, and for example, the first direction DR1 and the second direction DR2 may be perpendicular to each other. A third direction DR3 may be perpendicular to the first direction DR1 and the second direction DR2, respectively. However, the first direction DR1, the second direction DR2, and the third direction DR3 are not limited to three axes of a rectangular coordinate system, such as the x, y, and z axes, and may be interpreted in a broader sense. For example, the first direction DR1, the second direction DR2, and the third direction DR3 may be perpendicular to one another, or may represent different directions that are not perpendicular to one another.

The display device DD of the disclosure may be an organic light emitting display device (OLED), a liquid crystal display device (LCD), a field emission display device (FED), a plasma display device (PDP), an electrophoretic display device (EPD), or inorganic light emitting display device (ILED).

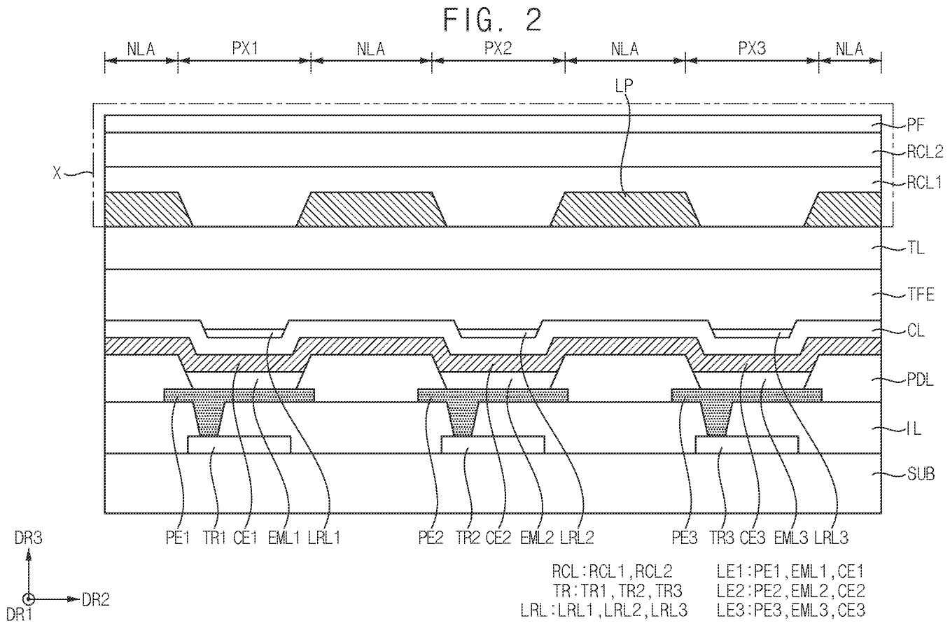

FIG. 2 is a schematic cross-sectional view taken along line I-I′ of FIG. 1.

Referring to FIG. 2, the display device DD according to an embodiment may include a substrate SUB, an insulating structure IL, a first, second, and third transistors TR1, TR2, TR3, a pixel defining layer PDL, a first pixel electrode PE1, a first light emitting layer EML1, a first common electrode CE1, a second pixel electrode PE2, a second light emitting layer EML2, a second common electrode CE2, a third pixel electrode PE3, a third light emitting layer EML3, a third common electrode CE3, a capping layer CL, a encapsulation layer TFE, a touch layer TL, a light blocking pattern LP, and a reflection adjustment layer RCL. The display device DD may include a light emitting area and a non-light emitting area. The light emitting area PX1, PX2, PX3 may be area in which the light emitting element LE1, LE2, LE3 is disposed to emit light of a specific wavelength band. The non-light emitting area NLA may be a region in which the light emitting element LE1, LE2, LE3 is not disposed and a region from which light is not emitted because light emitted from the light emitting element LE1, LE2, LE3 does not reach.

A first light emitting element LE1 may include a first pixel electrode PE1, a first light emitting layer EML1, and a first common electrode CE1, a second light emitting element LE2 may include a second pixel electrode PE2, a second light emitting layer EML2, and a second common electrode CE2, and a third light emitting element LE3 may include a third pixel electrode PE3, a third light emitting layer EML3, and a third common electrode CE3.

A substrate SUB may include a transparent material or an opaque material. In an embodiment, the substrate SUB may be a transparent resin substrate. Examples of the transparent resin substrate may include a polyimide substrate. In an embodiment, the polyimide substrate may include a first organic layer, a first barrier layer, a second organic layer, and the like. In an embodiment, the substrate SUB may include a quartz substrate, a synthetic quartz substrate, a calcium fluoride substrate, a fluorine-doped quartz substrate, a soda lime substrate, a non-alkali glass substrate, the like, or a combination thereof. These materials may be used alone or in combination with each other.

A transistor TR may be disposed on the substrate SUB. In an embodiment, the transistor TR may include amorphous silicon, polycrystalline silicon, or a metal oxide semiconductor.

The metal oxide semiconductor may include a binary compound (ABₓ), a ternary compound (ABₓC_{y}), a quaternary compound (ABₓC_{y}D_{z}) containing indium (In), zinc (Zn), gallium (Ga), tin (Sn), titanium (Ti), aluminum (Al), hafnium (Hf), zirconium (Zr), magnesium (Mg), and the like. For example, the metal oxide semiconductor may include zinc oxide (ZnOₓ), gallium oxide (GaOₓ), tin oxide (SnOₓ), indium oxide (InOₓ), indium gallium oxide (IGO), indium zinc oxide (IZO), indium tin oxide (ITO), indium zinc tin oxide (IZTO), indium gallium zinc oxide (IGZO), the like, or a combination thereof. These materials may be used alone or in combination with each other.

An insulating structure IL may be disposed on the substrate SUB. The insulating structure IL may cover the transistor TR. The insulating structure IL may include at least one inorganic insulating layer and at least one organic insulating layer. In an embodiment, the inorganic insulating layer may include silicon oxide (SiOₓ), silicon nitride (SiNₓ), silicon carbide (SiCₓ), silicon oxynitride (SiOₓN_{y}), silicon oxycarbide (SiOₓC_{y}), the like, or a combination thereof. In an embodiment, the organic insulating layer may include a photoresist, a polyacryl-based resin, a polyimide-based resin, a polyamide-based resin, a siloxane-based resin, an acryl-based resin, an epoxy-based resin, the like, or a combination thereof. These materials may be used alone or in combination with each other.

A first pixel electrode PE1, a second pixel electrode PE2, and the third pixel electrode PE3 may be disposed in first to third pixels PX1, PX2, and PX3 on the insulating structure IL, respectively. Each of the first to third pixel electrodes PE1, PE2, and PE3 may be connected to the first to third transistors TR1, TR2, and TR3, respectively, through a contact hole formed by removing a portion of the insulating structure IL. For example, each of the first to third pixel electrodes PE1, PE2, and PE3 may include a metal, an alloy, a metal nitride, a conductive metal oxide, a transparent conductive material, the like, or a combination thereof. These materials may be used alone or in combination with each other. For example, each of the first to third pixel electrodes PE1, PE2, and PE3 may operate as an anode.

A pixel defining layer PLD may be disposed in the non-light emitting area NLA on the insulating structure IL and the first to third pixel electrodes PE1, PE2, PE3. The pixel defining layer PLD may cover both sides of the first to third pixel electrodes PE1, PE2, PE3 and may expose top surfaces of the first to third pixel electrodes PE1, PE2, PE3. The pixel defining layer PDL may include an organic material and/or an inorganic material. In an embodiment, the pixel defining layer PDL may include an organic material. For example, the pixel defining layer PDL may include a photoresist, a polyacrylic resin, a polyimide resin, a polyamide resin, a siloxane resin, an acrylic resin, an epoxy resin, the like, or a combination thereof. These materials may be used alone or in combination with each other.

A first light emitting layer EML1, a second light emitting layer EML2, and a third light emitting layer EML3 may be disposed on the first to third pixel electrodes PE1, PE2, PE3, respectively. For example, the hole provided by the first to third pixel electrodes PE1, PE2, PE3 and the electron provided by the first to third common electrodes CE1, CE2, CE3 may combine in the first to third light emitting layer EML1, EML2, EML3, respectively, to form an exciton, and the first to third light emitting layer EML1, EML2, EML3 may emit light as the exciton changes from an excited state to a ground state.

The first to third common electrodes CE1, CE2, CE3 may be disposed on the first to third light emitting layers EML1, EML2, EML3 and the pixel defining layer PDL. In an embodiment, as shown in FIG. 2, the first to third common electrodes CE1, CE2, CE3 may be integral with each other. However, the disclosure is not limited thereto. In an embodiment, the first to third common electrodes CE1, CE2, CE3 may include a metal, an alloy, a metal nitride, a conductive metal oxide, a transparent conductive material, the like, or a combination thereof. These materials may be used alone or in combination with each other. For example, each of the first to third common electrodes CE1, CE2, CE3 may operate as cathodes.

A capping layer CL may be disposed on the first to third common electrodes CE1, CE2, CE3. The capping layer CL may be disposed on an entire area of the first to third common electrodes CE1, CE2, CE3. The capping layer CL may perform a function of protecting the first to third common electrodes CE1, CE2, CE3. For example, the capping layer CL may include an organic material and/or an inorganic material.

An anti-reflection layer LRL may be disposed in each of the first to third pixels PX1, PX2, PX3 on the capping layer CL. The anti-reflection layer LRL may include a surface. Light incident from the outside of the display device (e.g., the display device DD of FIG. 1) and reflected from the surface of the anti-reflection layer LRL may cause offset interference with light incident from the outside of the display device and reflected from the surfaces of the first to third common electrodes CE1, CE2, CE3. Accordingly, the anti-reflection layer LRL may prevent the display quality of the display device from decreasing as the external light is reflected. According to the disclosure, since the anti-reflection layer LRL suppresses reflection of external light, a separate polarization film may not be necessary. Accordingly, the thickness of the display device may be reduced, and the flexibility of the display device may be increased. In another embodiment, the anti-reflection layer LRL may be disposed on an entire upper surface of the capping layer CL. In an embodiment, the anti-reflection layer LRL may include at least one of bismuth (Bi), ytterbium (Yb), tungsten (W), and tungsten trioxide (WO₃). However, the disclosure is not limited thereto, and the anti-reflection layer LRL may include different types of materials.

An encapsulation layer TFE may be disposed on the capping layer CL and the anti-reflection layer LRL. The encapsulation layer TFE may prevent impurities, moisture, and the like from penetrating into the first to third light emitting elements LE1, LE2, LE3 from the outside. The encapsulation layer TFE may include at least one inorganic encapsulation layer and at least one organic encapsulation layer. For example, the inorganic encapsulation layer may include silicon oxide, silicon nitride, silicon oxynitride, or a combination thereof, and the organic encapsulation layer may include a polymer cured product such as polyacrylate.

A sensing layer TL may be disposed on the encapsulation layer TFE. Multiple sensing electrodes (not illustrated) may be formed in the sensing layer TL, and a user's touch may be sensed.

Alight blocking pattern LP may be disposed on the sensing layer TL. The light blocking patterns LP may be spaced apart from each other. In an embodiment, the light blocking pattern LP may be disposed in the non-light emitting area NLA. In an embodiment, the light blocking pattern LP may not be disposed in the first to third pixels PX1, PX2, PX3.

Light emitted from the first light emitting element LE1, the second light emitting element LE2, and the third light emitting element LE3 may be incident on the light blocking pattern LP or may pass between the light blocking patterns LP. Light incident on the light blocking pattern LP may be reflected from the light blocking pattern LP, transmitted through the light blocking pattern LP, or absorbed by the light blocking pattern LP. In an embodiment, most of the light incident on the light blocking pattern LP may be absorbed into the light blocking pattern LP. Accordingly, the light blocking pattern LP may control a viewing angle of the display device DD.

The light blocking pattern LP may include an inorganic material and/or an organic material. For example, the organic material may include a photoresist, a polyacrylic resin, a polyimide resin, a polyamide resin, a siloxane resin, an acrylic resin, an epoxy resin, the like, or a combination thereof. These materials may be used alone or in combination with each other.

The light blocking pattern LP may further include a light blocking material to serve as a black matrix. In an embodiment, the light blocking pattern LP may include a light blocking material such as a black pigment, a black dye, carbon black, or a combination thereof. These materials may be used alone or in combination with each other. In another embodiment, the light blocking pattern LP may include a colorant. For example, the colorant may include an orange pigment, a violet pigment, a blue pigment, the like, or a combination thereof. These materials may be used alone or in combination with each other.

A reflection adjustment layer RCL may be disposed on the encapsulation layer TFE. In an embodiment, the reflection adjustment layer RCL may include a dye or pigment. The reflection adjustment layer RCL may include a first portion RCL1 and a second portion RCL2 disposed on the first portion RCL1. In an embodiment, the reflection adjustment layer RCL may cover the light blocking pattern LP. The curing rate of the first portion RCL1 and the curing rate of the second portion RCL2 may be different from each other. In an embodiment, the curing rate of the second portion RCL2 may be greater than the curing rate of the first portion RCL1.

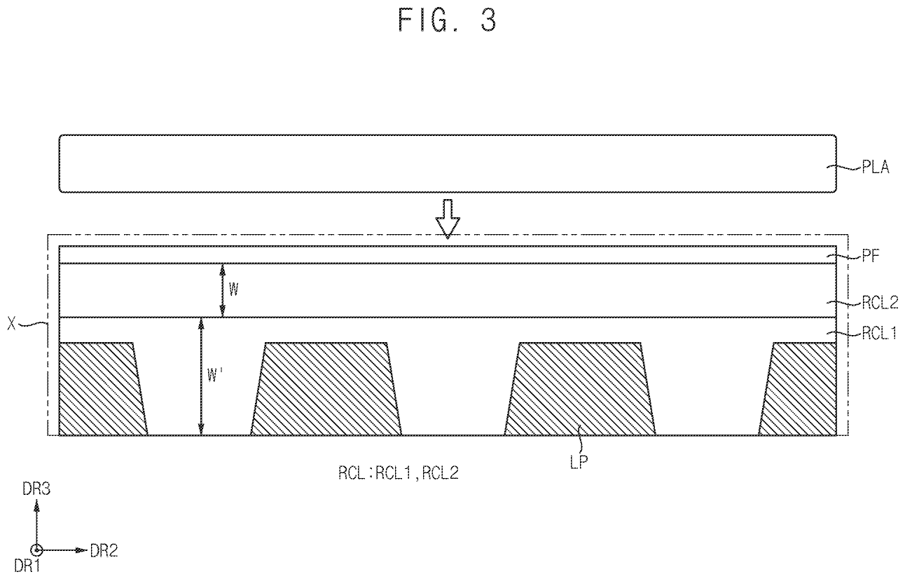

FIG. 3 is a schematic cross-sectional view illustrating region X of FIG. 2.

For example, FIG. 3 is a schematic cross-sectional view illustrating a reflection adjustment layer RCL according to an embodiment of the disclosure.

Referring to FIG. 3, The reflection adjustment layer RCL may be cured through a plasma dry etching process. The plasma PLA may harden the surface of the reflection control layer RCL during the plasma dry etching process to form a first portion RCL1 and a second portion RCL2 having different curing rates. The reflection adjustment layer RCL before the plasma dry etching process may include an acrylate monomer. As the plasma dry etching process proceeds, the acrylate monomer may be converted into an acrylate network. For example, as the acrylate monomer is converted into the acrylate network, the reflection adjustment layer RCL may be cured. During the plasma dry etching process, the plasma PLA may cure the surface of the reflection adjustment layer RCL. Therefore, the curing rate of the second portion RCL2 on the first portion RCL1 may be greater than the curing rate of the first portion RCL1. For example, the ratio of the acrylate network to the acrylate monomer included in the second portion RCL2 may be greater than the ratio of the acrylate network to the acrylate monomer included in the first portion RCL1.

After the plasma dry etching process, the curing rate of the first portion RCL1 and the second portion RCL2 may be measured by a Fourier Transform Infrared Spectroscopy. For example, the acrylate conversion rate of the first portion RCL1 and the second portion RCL2 of the reflection adjustment layer RCL may be measured by the Fourier transform infrared spectroscopy. The acrylate conversion rate may be a degree of which the acrylate monomer, which was not converted into the acrylate network during the plasma dry etching process, is converted into the acrylate network when the curing rates of the first portion RCL1 and the second portion RCL2 are measured by the Fourier transform infrared spectrometer. For example, the lower the acrylate conversion rate is, the higher the curing rate of the reflection adjustment layer RCL after the plasma dry etching process may be. In an embodiment, the acrylate conversion rate of the second portion RCL2 may be greater than or equal to about 0.1 times of an acrylate conversion rate of the first portion RCL1. In an embodiment, the acrylate conversion rate of the second portion RCL2 may be in a range of about 0.1 times to about 0.3 times of the acrylate conversion rate of the first portion RCL1.

In an embodiment, a thickness W of the second portion RCL2 in a thickness direction of the substrate (the third direction DR3) may be in a range of about 0.1 times to about 0.9 times of a sum of a thickness W′ of the first portion RCL1 and a thickness W of the second portion RCL2.

A protective film PF may be disposed on the reflection adjustment layer RCL. The protective film PF may protect the display device DD from external forces and impurities. In an embodiment, the protective film PF may include at least one of polyethylene terephthalate (PET), polypropylene (PP), a polyepoxy material, a cyclic olefin-based polymer (COP), a cyclic olefin-based copolymer (COC), a copolymer of a polycarbonate-based resin and a cyclic olefin-based copolymer, polymethylmethacrylate (PMMA), polycarbonate (PC), polyvinyl chloride, triacetylcellulose, and polyethylene naphthalate.

As mentioned above, the reflection adjustment layer RCL may include a dye or pigment. While the protective film PF is attached, the display device DD may be transported to another place. During the transportation process, the dye or pigment of the reflection adjustment layer RCL may move into the protective film PF. Accordingly, the characteristics of the display device DD may be changed or the quality of the display device DD may be lowered. According to an embodiment of the disclosure, the dye or pigment may be prevented from moving from the reflection adjustment layer RCL to the protective film PF by disposing the first portion RCL1 and the second portion RCL2 which have different curing rates by curing the surface of the reflection adjustment layer RCL.

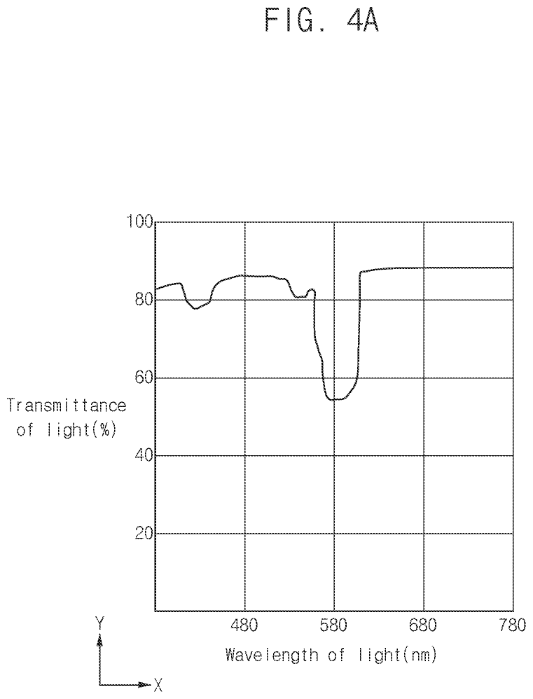

FIGS. 4A and 4B are experimental data showing transmittance of a protective film according to a comparative embodiment and an embodiment.

Referring to FIG. 3, FIG. 4A, and FIG. 4B, X-axis may represent a wavelength (nm) of light passing through the protective film PF. Y-axis may indicate the transmittance (%) of light of the protective film PF. FIG. 4A illustrates the transmittance (%) of light of the protective film PF according to the comparative embodiment. As described above, as the pigment or dye of the reflection adjustment layer RCL moves into the protective film PF, the transmittance in the protective film PF of light having a wavelength of about 580 nm may be significantly lowered. FIG. 4B illustrates the transmittance (%) of light in the protective film PF according to an embodiment of the disclosure. Since the dye or pigment does not move to the protective film PF, transmittance of the protective film PF may be maintained constant.

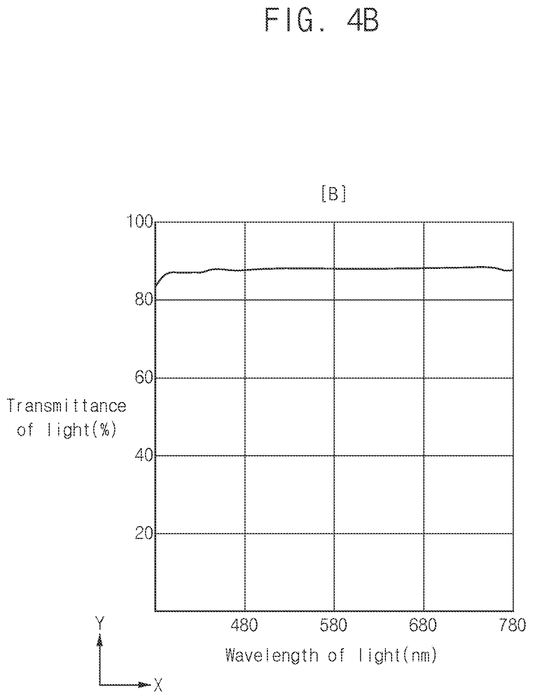

FIGS. 5 to 11 are schematic cross-sectional views illustrating a method of manufacturing the display device of FIG. 2 according to an embodiment.

Referring to FIG. 5, the transistor TR may be formed on the substrate SUB. The substrate SUB may include a transparent material or an opaque material. For example, the substrate SUB may be a transparent resin substrate. For example, the transistor TR may be formed using amorphous silicon, crystalline silicon, or a metal oxide semiconductor.

The insulating structure IL may be formed on the substrate SUB. The insulating structure IL may cover the transistor TR. For example, the insulating structure IL may be formed by at least one inorganic insulating layer and at least one organic insulating layer.

The first to third pixel electrodes PE1, PE2, PE3 may be formed in the first to third pixels PX1, PX2, PX3 on the insulating structure IL, respectively. The first to third pixel electrodes PE1, PE2, and PE3 may be connected to the first to third transistor TR1, TR2, TR3, respectively, through a contact hole formed by removing a portion of the insulating structure IL. For example, the first to third pixel electrodes PE1, PE2, PE3 may be formed using a metal, an alloy, a metal nitride, a conductive metal oxide, a transparent conductive material, the like, or a combination thereof.

The pixel defining layer PDL may be formed in the non-light emitting area NLA on the insulating structure IL and the first to third pixel electrodes PE1, PE2, PE3. The pixel defining layer PDL may have an opening exposing a portion of the top surfaces of the first to third pixel electrodes PE1, PE2, PE3. The pixel defining layer PDL may be formed using an organic material and/or an inorganic material.

The first to third light emitting layers EML1, EML2, EML3 may be formed on the first to third pixel electrodes PE1, PE2, PE3, respectively. For example, the first to third light emitting layers EML1, EML2, EML3 may be formed inside the opening of the pixel defining layer PDL. For example, the first to third light emitting layers EML1, EML2, EML3 may be formed using a low-molecular organic compound and/or a high-molecular organic compound.

The first to third common electrodes CE1, CE2, CE3 may be formed on the first to third light emitting layers EML1, EML2, EML3 and the pixel defining layer PDL. The first to third common electrodes CE1, CE2, CE3 may be formed in an entire area of the first to third pixels PX1, PX2, PX3 and the non-light emitting area NLA. For example, the first to third common electrodes CE1, CE2, CE3 may be formed using a metal, an alloy, a metal nitride, a conductive metal oxide, a transparent conductive material, the like, or a combination thereof.

Accordingly, the first to third light emitting elements LE1, LE2, LE3 including the first to third pixel electrodes PE1, PE2, PE3, the first to third light emitting layers EML1, EML2, EML3, and the first to third common electrodes CE1, CE2, CE3 may be formed in the first to third pixels PX1, PX2, PX3 on the substrate SUB, respectively.

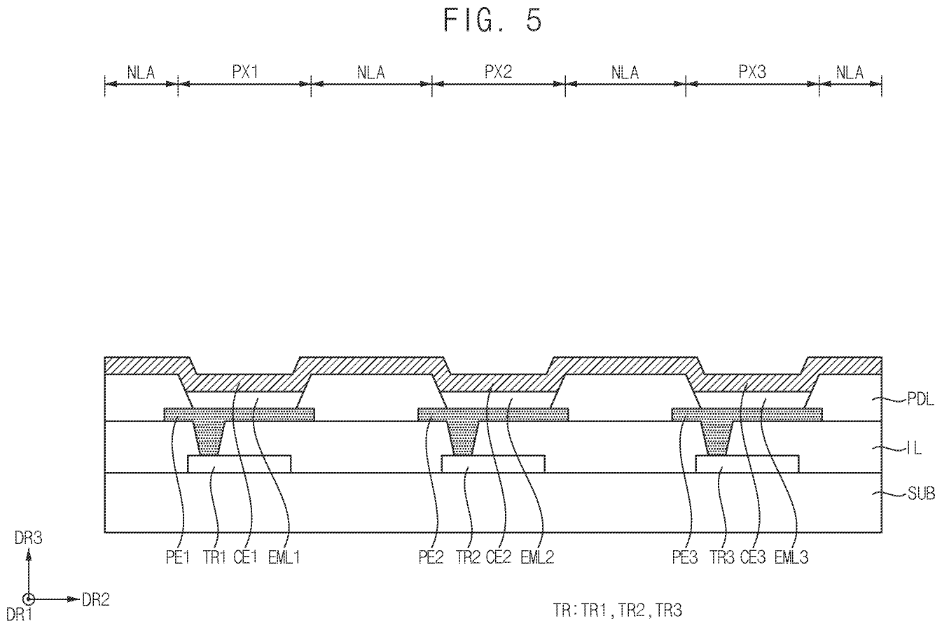

Referring to FIG. 6, the capping layer CL may be formed on the first to third common electrodes CE1, CE2, CE3. The capping layer CL may be formed on an entire surface of the first to third common electrodes CE1, CE2, CE3. For example, the capping layer CL may be formed using an inorganic material and/or an organic material.

The First to third anti-reflection layers LRL1, LRL2, LRL3 may be formed in the first to third pixels PX1, PX2, PX3 on the capping layer CL, respectively. However, the disclosure is not limited thereto, and in another embodiment, the anti-reflection layer LRL may be formed on an entire surface of the capping layer CL.

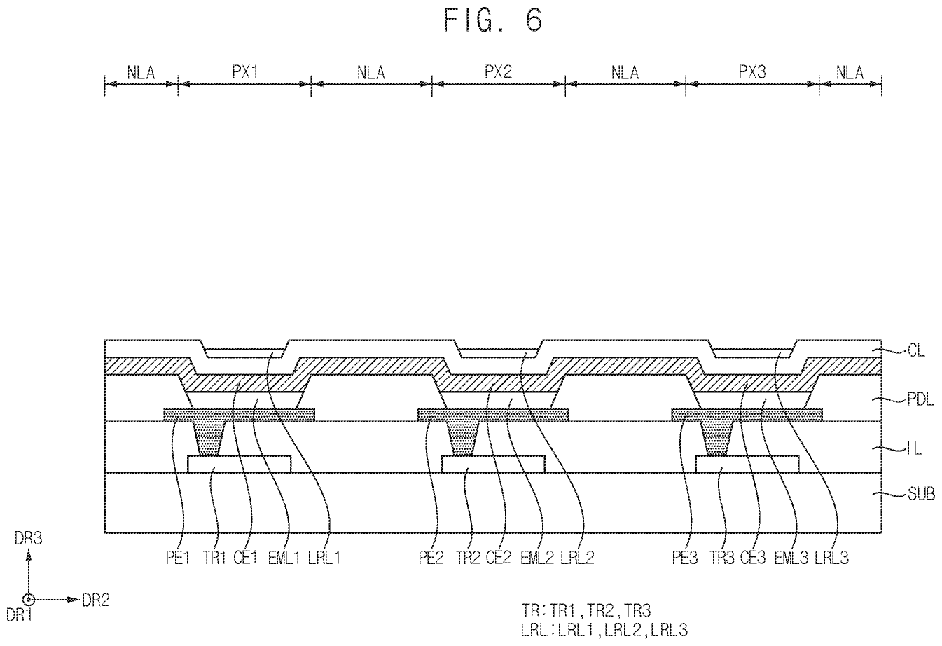

Referring to FIG. 7, the encapsulation layer TFE may be formed on the capping layer CL and the anti-reflection layer LRL. The encapsulation layer TFE may be formed in the entire first to third pixels PX1, PX2, PX3 and the non-light emitting area NLA. For example, the encapsulation layer TFE may be formed using an inorganic material and an organic material.

The sensing layer TL may be formed on the encapsulation layer TFE. The sensing layer TL may be formed in the entire first to third pixels PX1, PX2, PX3 and the non-light emitting area NLA. Multiple sensing electrodes may be formed in the sensing layer TL.

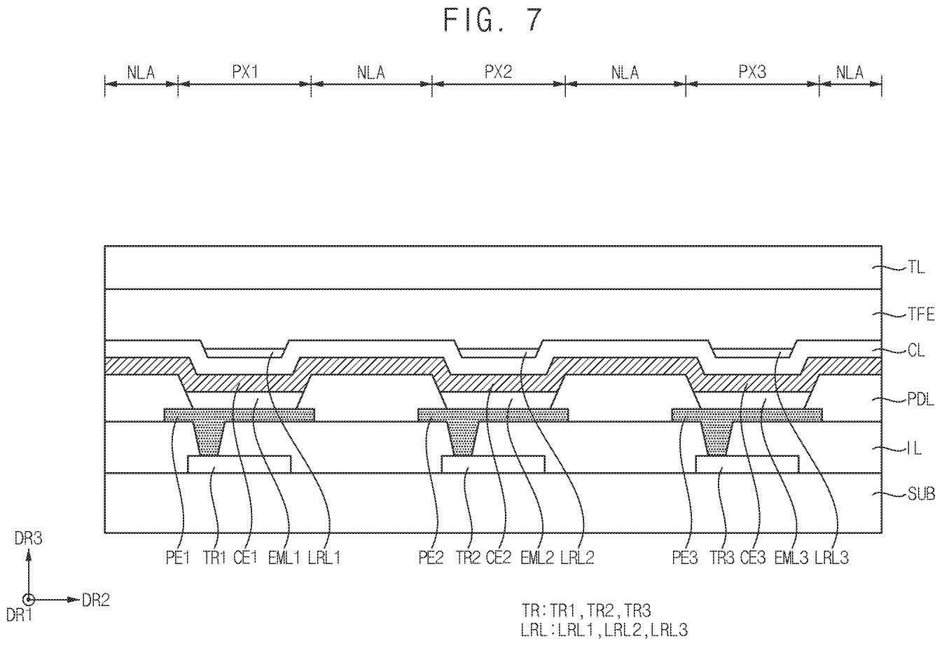

Referring to FIG. 8, the light blocking pattern LP may be formed on the sensing layer TL. The light blocking patterns LP may be spaced apart from each other. In an embodiment, the light blocking pattern LP may be disposed in the non-light emitting area NLA. In an embodiment, the light blocking pattern LP may not be disposed in the first to third pixels PX1, PX2, PX3. The light blocking pattern LP may be formed of an inorganic material.

The light blocking pattern LP may include a light blocking material to serve as a black matrix. In an embodiment, the light blocking pattern LP may include a light blocking material such as a black pigment, a black dye, carbon black, the like, or a combination thereof. These materials may be used alone or in combination with each other. In another embodiment, the light blocking pattern LP may include a colorant. For example, the colorant may include an orange pigment, a violet pigment, a blue pigment, the like, or a combination thereof. These materials may be used alone or in combination with each other.

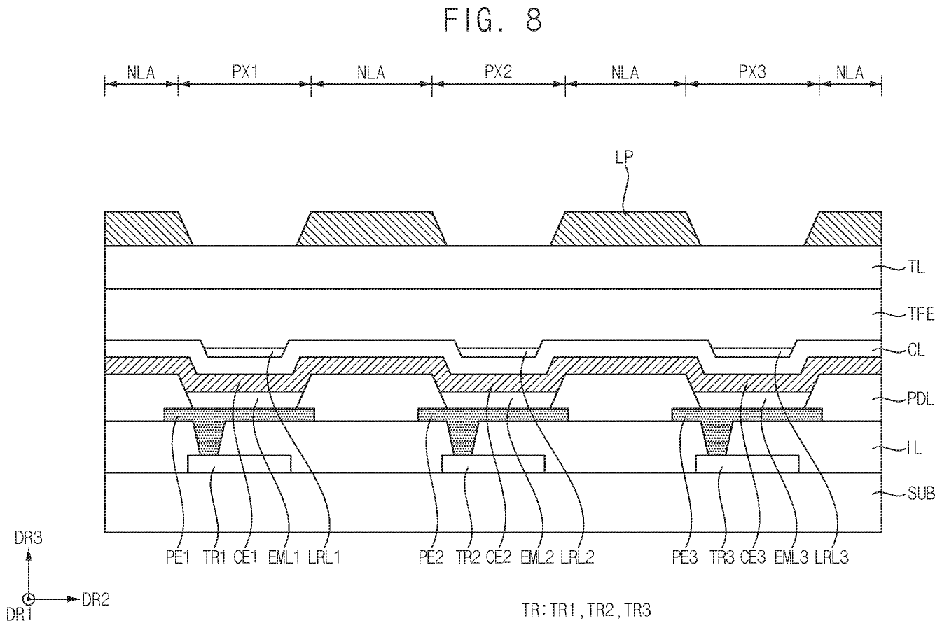

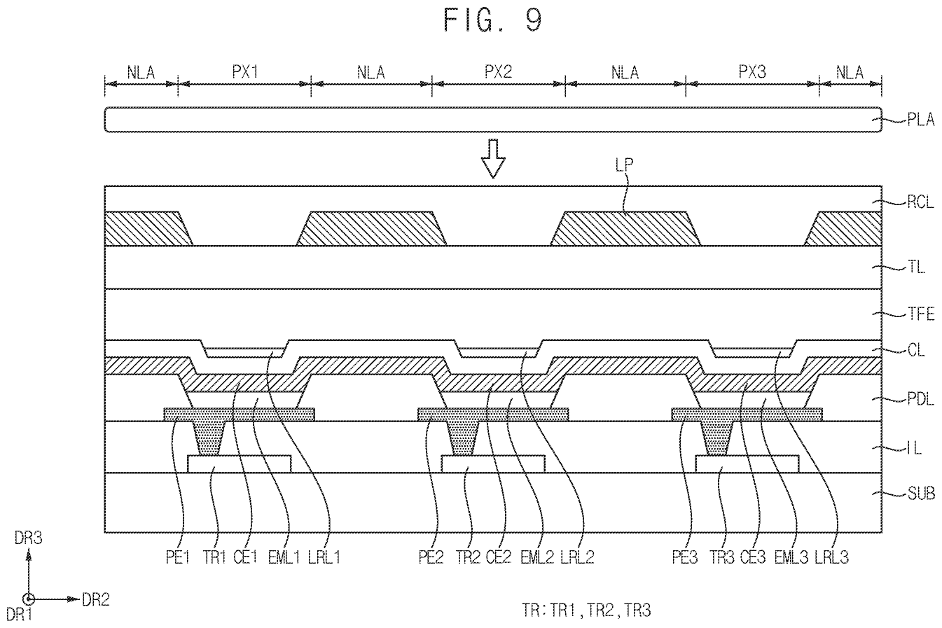

Referring to FIGS. 9 and 10, a reflection adjustment layer RCL may be formed on the light blocking pattern LP and the sensing layer TL. In an embodiment, the reflection adjustment layer RCL may cover the light blocking pattern LP. In an embodiment, the reflection adjustment layer RCL may include an acrylate monomer.

The plasma PLA may cure the surface of the reflection adjustment layer RCL through the plasma dry etching process. For example, during the plasma dry etching process, plasma PLA may cure the reflection adjustment layer RCL by converting the acrylate monomer into the acrylate network. The plasma dry etching process may be performed from the surface of the reflection adjustment layer RCL. Accordingly, the reflection adjustment layer RCL may include portions having different curing rates. For example, the reflection adjustment layer RCL may include a first portion RCL1 and a second portion RCL2 having a curing rate greater than a curing rate of the first portion RCL1.

In an embodiment, the reflection adjustment layer RCL may include a dye or pigment.

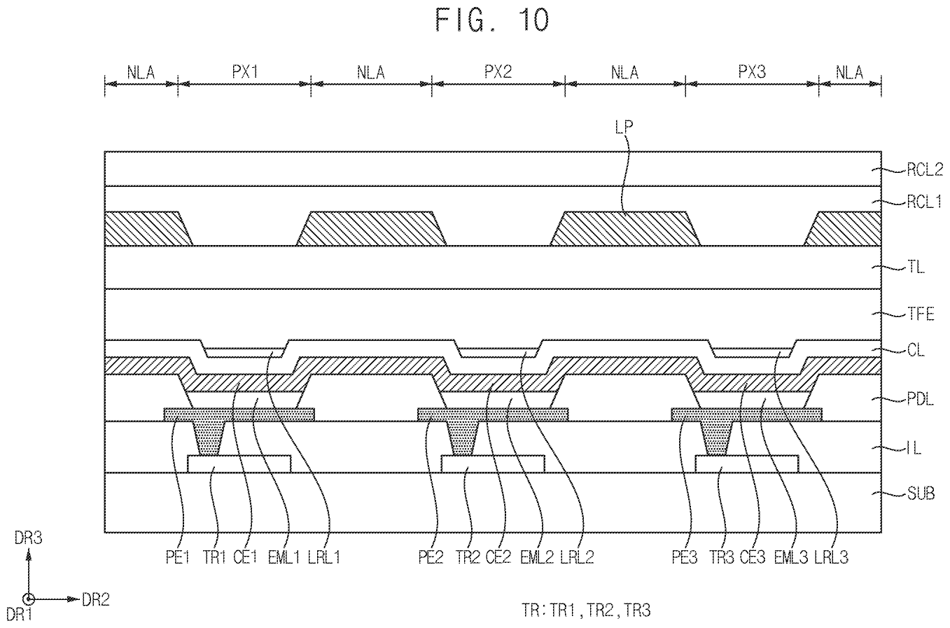

Referring to FIG. 11, a protective film PF may be formed on the second portion RCL2 of the reflection adjustment layer RCL. In an embodiment, The protective film PF may include at least one of polyethylene terephthalate (PET), polypropylene (PP), a polyepoxy material, a cyclic olefin-based polymer (COP), a cyclic olefin-based copolymer (COC), a copolymer of a polycarbonate-based resin and a cyclic olefin-based copolymer, polymethylmethacrylate (PMMA), polycarbonate (PC), polyvinyl chloride, triacetylcellulose, and polyethylene naphthalate.

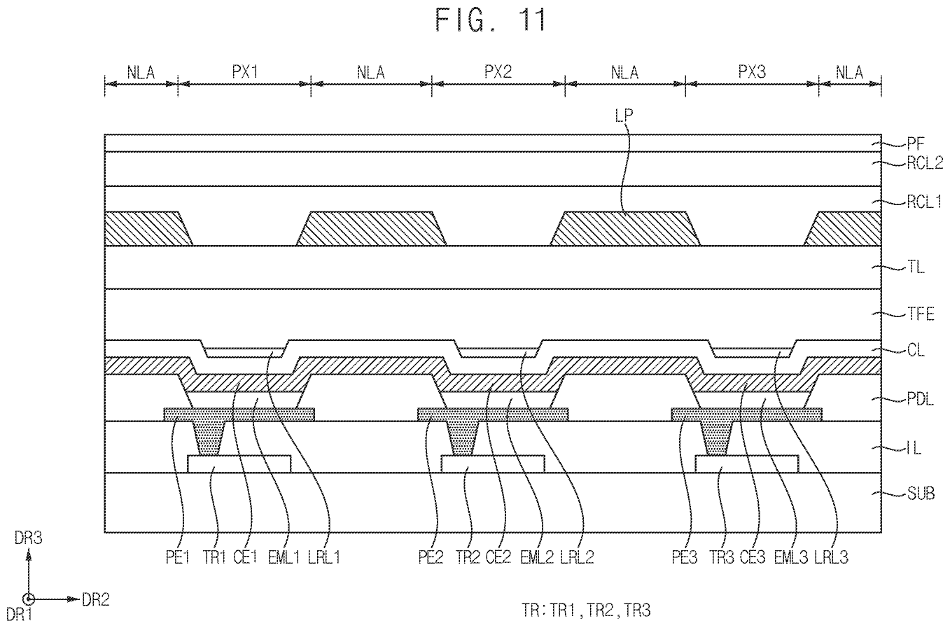

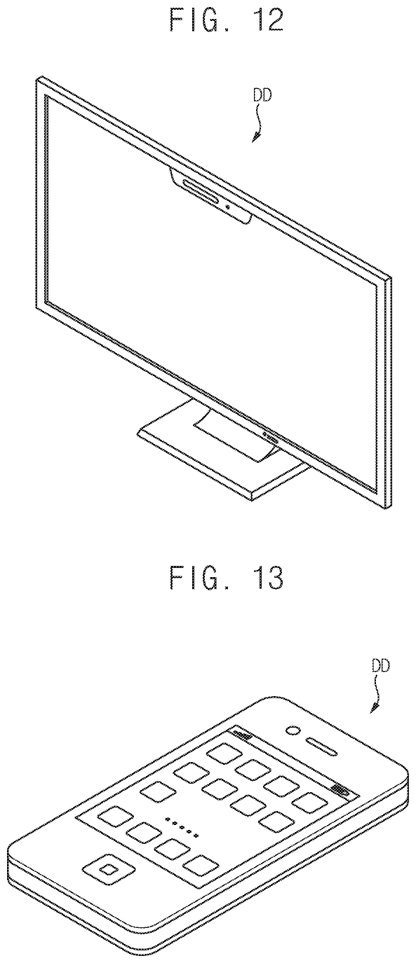

FIG. 12 is a schematic diagram illustrating the display device of FIG. 1 implemented as a television according to an embodiment. FIG. 13 is a schematic diagram illustrating the display device of FIG. 1 implemented as a smart phone according to an embodiment.

Referring to FIGS. 12 and 13, the display device DD may be implemented as a television. In another embodiment, the display device DD may be implemented as a smartphone. However, the display device DD is not limited thereto, and may be implemented as, for example, a mobile phone, a video phone, a smart pad, a smart watch, a tablet PC, a vehicle navigation, a computer monitor, a laptop, a head mounted display (HMD), and the like.

The above description is an example of technical features of the disclosure, and those skilled in the art to which the disclosure pertains will be able to make various modifications and variations. Thus, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a substrate including a light emitting area and a non-light emitting area;
a light emitting element disposed in the light emitting area on the substrate;
an encapsulation layer disposed on the light emitting element; and
a reflection adjustment layer disposed on the encapsulation layer, wherein the reflection adjustment layer comprises a first portion adjacent to the encapsulation layer and a second portion disposed on the first portion, and
a curing rate of the first portion and a curing rate of the second portion are different.

2. The display device of claim 1, wherein the curing rate of the second portion is greater than the curing rate of the first portion.

3. The display device of claim 1, wherein the reflection adjustment layer includes an acrylate monomer and an acrylate network.

4. The display device of claim 3, wherein an acrylate conversion rate of the second portion is greater than or equal to about 0.1 times of an acrylate conversion rate of the first portion.

5. The display device of claim 4, wherein the acrylate conversion rate of the second portion is in a range of about 0.1 times to about 0.3 times of the acrylate conversion rate of the first portion.

6. The display device of claim 3, wherein a ratio of the acrylate network to the acrylate monomer included in the second portion is greater than a ratio of the acrylate network to the acrylate monomer included in the first portion.

7. The display device of claim 1, wherein a thickness of the second portion is in a range of about 0.1 times to about 0.9 times of a sum of a thickness of the first portion and the thickness of the second portion in a thickness direction of the substrate.

8. The display device of claim 1, further comprising:
a light blocking pattern disposed on the encapsulation layer.

9. The display device of claim 8, wherein the reflection adjustment layer covers the light blocking pattern.

10. The display device of claim 1, further comprising:
a capping layer disposed on the light emitting element; and
an antireflection layer disposed between the capping layer and the encapsulation layer and including an inorganic material.

11. The display device of claim 10, wherein the antireflection layer includes at least one of bismuth (Bi), ytterbium (Yb), tungsten (W), and tungsten trioxide (WO₃).

12. The display device of claim 1, wherein the reflection adjustment layer includes a dye or a pigment.

13. The display device of claim 1, wherein the first portion and the second portion are cured by a plasma dry etching process.

14. The display device of claim 1, further comprising:
a protective film disposed on the second portion.

15. A method of manufacturing a display device comprising:
forming a light emitting element on a substrate including a light emitting area and a non-light emitting area;
forming an encapsulation layer on the light emitting element;
forming a reflection adjustment layer on the encapsulation layer; and
forming a first portion adjacent to the encapsulation layer and a second portion disposed on the first portion by curing a surface of the reflection adjustment layer,
wherein a curing rate of the first portion and a curing rate of the second portion are different.

16. The method of claim 15, wherein the curing rate of the second portion is greater than the curing rate of the first portion.

17. The method of claim 15, wherein the curing of the surface of the reflection adjustment layer is performed by a plasma dry etching process.

18. The method of claim 15, wherein the curing of the surface of the reflection adjustment layer includes converting an acrylate monomer into an acrylate network by curing the acrylate monomer included in the reflection adjustment layer.

19. The method of claim 15, further comprising:
forming a capping layer on the light emitting element; and
forming an antireflection layer including an inorganic material between the capping layer and the encapsulation layer.

20. The method of claim 15, further comprising:
forming a protective film on the reflection adjustment layer.
